(19) United States
(12) Patent Application Publication
(10) Pub. No.: US 2017/0115332 A1
(43) Pub. Date: Apr. 27, 2017

(54) ELECTRICITY CONSUMPTION PREDICTING SYSTEM AND ELECTRICITY CONSUMPTION PREDICTING METHOD APPLIED FOR PROCESSING MACHINE

(71) Applicant: INSTITUTE FOR INFORMATION INDUSTRY, Taipei (TW)

(72) Inventors: Hung-Sheng CHIU, Taipei City (TW); Jun-Ren CHEN, Taichung City (TW); Hung-An KAO, Taipei City (TW); Cheng-Hui CHEN, Nantou County (TW); Yung-Yi HUANG, Nantou County (TW); Hsiao-Chen CHANG, Taipei City (TW)

(21) Appl. No.: 15/145,813

(22) Filed: May 4, 2016

(30) Foreign Application Priority Data
Oct. 27, 2015 (TW) 104135264

(51) Int. Cl. G01R 21/133; G06N 5/02

(52) U.S. Cl. CPC G01R 21/133; G06N 5/02

(57) ABSTRACT

An electricity consumption predicting system includes a knowledge database, a decomposition module, a mapping module and a predicting module. The knowledge database stores model information. The module information records a corresponding relation between each of a plurality of NC program blocks and an electricity consumption value thereof. The decomposition module decomposes a processing program into the NC program blocks, and acquires processing information corresponding to the each of the NC program blocks. The mapping module generates a predictive block electricity consumption value of the each of the NC program blocks according to the NC program blocks, the corresponding processing information and the model information. The predicting module sums up the predictive block electricity consumption values corresponding to the NC program blocks to generate a predictive processing program electricity consumption value.

### RELATED APPLICATIONS

This application claims priority to Taiwan Application Serial Number 104135264, filed Oct. 27, 2015, which is herein incorporated by reference.

### BACKGROUND

Technical Field

The present invention relates to an electricity consumption predicting technology. More particularly, the present invention relates to an electricity consumption predicting system and an electricity consumption predicting method applied for a processing machine.

Description of Related Art

Cost control is a key point for enterprises to earn profits. Electricity cost is a major part of the processing cost for manufacturing industries, especially for industries that use processing machine to produce work pieces. In prior art, manufacturing industries mostly control electricity consumption through a smart electricity meter to record electricity consumption values of the whole factory. The recorded electricity consumption values by the smart electricity meter is taken as a basis for calculating or predicting a required electricity consumption value per month of the factory, and even determining an electricity consumption quota of the factory. Although the smart electricity meter can measure a total electricity consumption value of the whole factory, electricity consumption values of the processing machine operation has large variance because of different times, processing hours of the processing machine, processing methods and processed work pieces. Therefore, the total electricity consumption value of the factory that is previously measured cannot be used for predicting a future electricity consumption value. Moreover, an electricity consumption value of the every processing machine also cannot be precisely known from the total electricity consumption value of the factory so that electricity consumption cost of an order cannot be predicted and effective improvement strategy cannot be decided.

### SUMMARY

In order to predict a total electricity consumption value of a processing machine during production, and improve accuracy of predicting the total electricity consumption value of the processing machine, an aspect of the present disclosure provides an electricity consumption predicting system applied for a processing machine. The electricity consumption predicting system includes a knowledge database, a decomposition module, a mapping module and a predicting module. The knowledge database is configured to store model information. The model information is used for recording corresponding relation between each of a plurality of NC program blocks and an electricity consumption value thereof. The decomposition module is configured to decompose a processing program into the NC program blocks and to acquire corresponding processing information corresponding to the each of the NC program blocks. The mapping module is configured to generate a predictive block electricity consumption value corresponding to the each of the NC program blocks according to the each of the NC program blocks, the corresponding processing information thereof and the model information. The predicting module is configured to sum up the plurality of predictive block electricity consumption values corresponding to the NC program blocks to generate a predictive processing program total electricity consumption value.

In an embodiment of the present disclosure, the electricity consumption predicting system further includes a model generating module. The model generating module is configured to generate a plurality of functional information according to a test processing program and test electricity consumption information, and to write the functional information into the knowledge database for storage, wherein the mapping module maps the functional information to make the model generating module generate the model information.

In an embodiment of the present disclosure, the electricity consumption predicting system further includes a data extracting module. The data extracting module is configured to extract the test processing program and the test electricity consumption information from a controller signal and an electricity meter signal respectively, and to send the test processing program and the test electricity consumption information to the model generating module.

In an embodiment of the present disclosure, the data extracting module extracts a corresponding practical electricity consumption information from the electricity meter signal according to the each of the NC program blocks, and sends the corresponding practical electricity consumption information to the decomposition module. The decomposition module updates the functional information in the knowledge database according to the each of the NC program blocks and the corresponding practical electricity consumption information. The mapping module further maps the updated functional information to update the model information.

In an embodiment of the present disclosure, when the predicting module determines that the predictive processing program total electricity consumption value doesn't meet an electricity consumption standard, the predicting module adjusts a corresponding processing information corresponding to a NC program block of the NC program blocks to generate an adjusted processing information and replaces the corresponding processing information with the adjusted processing information to update the corresponding processing information. The mapping module generates a plurality of predictive adjusted block electricity consumption values according to each of the NC program blocks, the corresponding processing information thereof and the model information. The predicting module sums up the predictive adjusted block electricity consumption values to generate a predictive adjusted processing program total electricity consumption value. When the predicting module determines that the predictive adjusted processing program total electricity consumption value meets the electricity consumption standard, the predicting module sends the adjusted processing information to a controller to adjust the processing program.

In an embodiment of the present disclosure, the model generating module writes the model information into the knowledge database.

In an embodiment of the present disclosure, the processing information comprises a moving distance information and a processing time information of a spindle of the processing machine calculated by the decomposition module according to the NC program blocks.

Another aspect of the present disclosure provides an electricity consumption predicting method applied for a processing machine, and the electricity consumption predicting method comprises steps as follows. A processing program is decomposed into a plurality of NC program blocks and acquiring a corresponding processing information corresponding to each of the NC program blocks. A predictive block electricity consumption value corresponding to the each of the NC program blocks is generated according to the each of the NC program blocks, the corresponding processing information thereof and a model information in a knowledge database, wherein the model information is used for recording a corresponding relation between the each of the NC program blocks and an electricity consumption value thereof. The predictive block electricity consumption values corresponding to the NC program blocks are summed up to generate a predictive processing program total electricity consumption value.

In an embodiment of the present disclosure, a plurality of functional information is generated according to a test processing program and a test electricity consumption information, and writing the functional information into the knowledge database for storage. The functional information is mapped to generate the model information.

In an embodiment of the present disclosure, the test processing program and the test electricity consumption information are extracted from a controller signal and an electricity meter signal respectively.

In an embodiment of the present disclosure, a corresponding practical electricity consumption information is extracted from the electricity meter signal according to the each of the NC program blocks. The functional information in the knowledge database is updated according to the each of the NC program blocks and the corresponding practical electricity consumption information. The updated functional information is mapped to update the model information.

In an embodiment of the present disclosure, a corresponding processing information corresponding to a NC program block of the NC program blocks is adjusted to generate an adjusted processing information when a determination is made in which the predictive processing program total electricity consumption value doesn't meet an electricity consumption standard. The corresponding processing information is replaced with the adjusted processing information to update the corresponding processing information. A plurality of predictive adjusted block electricity consumption values are generated according to the each of the NC program blocks, the corresponding processing information thereof and the model information. The predictive adjusted block electricity consumption values are summed up to generate a predictive adjusted processing program total electricity consumption value. The adjusted processing information is sent to a controller to adjust the processing program when a determination is made in which the predictive adjusted processing program total electricity consumption value meets the electricity consumption standard.

In an embodiment of the present disclosure, the model information is written into the knowledge database.

In an embodiment of the present disclosure, the processing information comprises a moving distance information and a processing time information of a spindle of the processing machine that are calculated according to the NC program blocks.

In conclusion, through the electricity consumption predicting system and the electricity consumption predicting method of the present disclosure, the present disclosure can only require the processing program that the processing machine performs on a work piece to generate the predictive processing program total electricity consumption value as a basis for estimating cost of the work piece electricity consumption value according to the model information in the knowledge database. Moreover, the present disclosure also can estimate the total electricity consumption value of the work piece produced by the processing machine according to an order quantity of the work piece, processing schedule and so on. Compared to prior art that use a smart electricity meter, the present disclosure can predicts the total electricity consumption value of work piece process before production, and the predicted total electricity consumption value is closer to electricity consumption value of the processing machine during an actual process so that the present disclosure significantly improves accuracy of predicting electricity consumption value. Therefore, the factory workers can estimate cost before the work piece production according to the predictive total electricity consumption value of the work piece. The predictive total electricity consumption value of the work piece can even used for managing processing schedule of the processing machine, or adjusting processing parameters of the processing machine appropriately.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic diagram of an electricity consumption predicting system applied for a processing machine according to an embodiment of the present disclosure;

FIG. 2 is a schematic diagram of an electricity consumption predicting system applied for a processing machine according to an embodiment of the present disclosure;

FIG. 3 is a schematic diagram of model information according to the present disclosure;

FIG. 4 is a schematic diagram of model information according to the present disclosure;

FIG. 5 is a schematic diagram of model information according to the present disclosure;

FIG. 6 is a schematic diagram of model information according to the present disclosure;

FIG. 7 is a flow chart of an electricity consumption predicting method applied for a processing machine according to an embodiment of the present disclosure;

FIG. 8 is a flow chart of an electricity consumption predicting method applied for a processing machine according to an embodiment of the present disclosure;

FIG. 9 is a flow chart of an electricity consumption predicting method applied for a processing machine according to an embodiment of the present disclosure;

FIG. 10 is a flow chart of an electricity consumption predicting method applied for a processing machine according to an embodiment of the present disclosure;

FIG. 11 is a flow chart of an electricity consumption predicting method applied for a processing machine according to an embodiment of the present disclosure;

FIG. 12A is a schematic diagram of proportional distribution of predictive processing program total electricity consumption value according to an embodiment of the present disclosure;

FIG. 12B is a schematic diagram of proportional distribution of predictive processing program total electricity consumption value according to an embodiment of the present disclosure; and

FIG. 13 is a schematic diagram of predictive block electricity consumption value according to an embodiment of the present disclosure.

### DETAILED DESCRIPTION

In order to make the description of the disclosure more detailed and comprehensive, reference will now be made in detail to the accompanying drawings and the following embodiments. However, the provided embodiments are not used to limit the ranges covered by the present disclosure; orders of step description are not used to limit the execution sequence either. Any devices with equivalent effect through rearrangement are also covered by the present disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise indicated, all numbers expressing quantities, conditions, and the like in the instant disclosure and claims are to be understood as modified in all instances by the term “about.” The term “about” refers, for example, to numerical values covering a range of plus or minus 20% of the numerical value. The term “about” preferably refers to numerical values covering range of plus or minus 10% (or most preferably, 5%) of the numerical value. The modifier “about” used in combination with a quantity is inclusive of the stated value.

When processing industry products work pieces, NC program blocks are designed according to processing instructions readable to a processing machine, formats of processing parameters, processes needed for the work pieces and so on. For example, a NC program block may be expressed as a NC code “G01 Z2.5 F200.” Specifically, G01 indicates move at feed rate, Z2.5 indicates 2.5 units (e.g., inch) in a z-axis, and F200 indicates that the feed rate is 200 units (e.g., mm/min). Therefore, the NC program block “G01 Z2.5 F200” indicates that moving at a feed rate to cut for 2.5 inches in the z-axis and the feed rate is 200 mm/min. As aforementioned, plural NC program blocks can be sequentially designed according to one or plural processes needed for a work piece, and all of the NC program blocks form the processing program of the work piece.

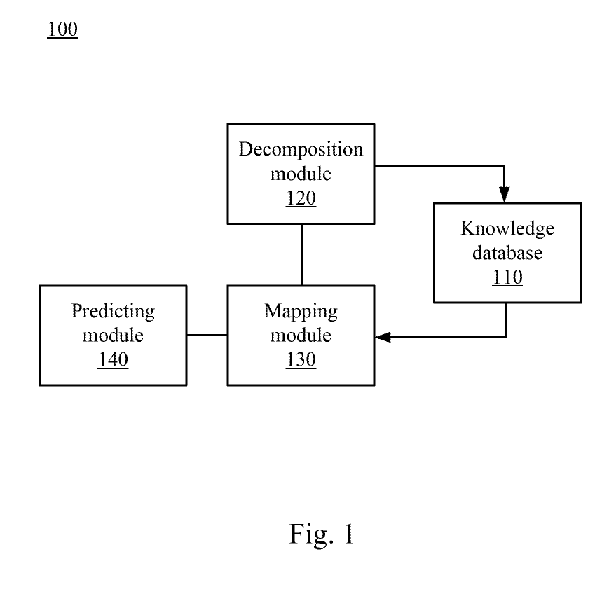

In order to predict an electricity consumption value of a processing program, that is, to predict an electricity consumption value of process for a work piece, reference is made to FIG. 1. FIG. 1 is a schematic diagram of an electricity consumption predicting system 100 applied for a processing machine according to an embodiment of the present disclosure. The electricity consumption predicting system 100 includes a knowledge database 110, a decomposition module 120, a mapping module 130 and a predicting module 140. The knowledge database 110 stores model information, and the model information is used for recording a corresponding relation between each of NC program blocks and an electricity consumption value thereof. The decomposition module 120 decomposes the processing program into a plurality of NC program blocks and acquires corresponding processing information corresponding to the each of the NC program blocks. The processing information includes processing parameters that can be acquired from the NC program blocks directly by the decomposition module 120 and processing parameters under calculation. For example, processing information includes a moving distance of the processing machine spindle (e.g., through a calculation that uses machine coordinate parameters and Euclid's principles), a processing time (e.g., through a calculation divides moving distance by moving speed), or another calculated parameter according to the NC program blocks.

The mapping module 130 generates a predictive block electricity consumption value corresponding to the each of the NC program blocks according to each of the NC program blocks, the corresponding processing information thereof and the model information. Specifically, the mapping module 130 determines an electricity consumption value in unit time according to the model information (e.g., a polynomial curve) in the knowledge database that processing parameters (e.g., an action, a rotational speed, a feed rate of the processing machine) of the NC program blocks are mapped to. For example, through the abovementioned mapping method, the mapping module 130 may determine an electricity consumption value when the processing machine is an idle state, a cutting state, a feeding state and so on. The mapping module 130 then generates plural predictive block electricity consumption values corresponding to the NC program blocks according to the electricity consumption value in unit time and the processing information (e.g., moving distance, processing time, etc). As aforementioned, the mapping module 130 can generate a predictive block electricity consumption value of the each of the NC program blocks. Details of the model information are described hereinafter.

The predicting module 140 sums up the plural predictive block electricity consumption values generated by the mapping module 130 to generate a predictive processing program total electricity consumption value of the processing program. As aforementioned, because the NC program blocks are decomposed from the processing program by the decomposition module 120, the predicting module 140 sums up the predictive block electricity consumption values corresponding to the each of the NC program blocks to generate a predictive electricity consumption value corresponding to the processing program, i.e., the predictive processing program total electricity consumption value.

As a result, only requiring a processing program of a work piece, the electricity consumption predicting system 100 of the present disclosure can generate a predictive electricity consumption value of the processing program as a basis for estimating cost of the work piece electricity consumption value according to the model information in the knowledge database 110.

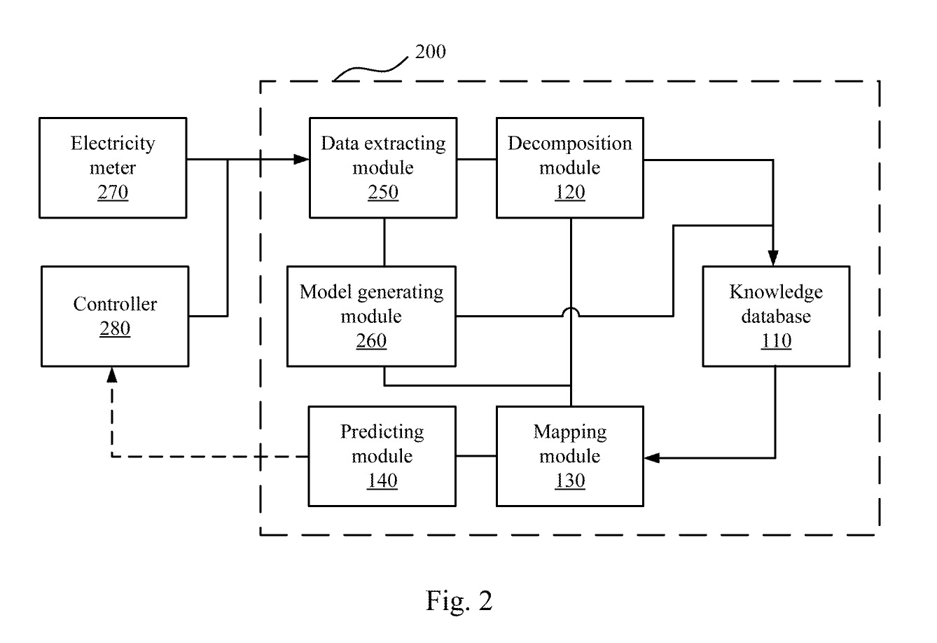

In order to describe generating method of the model information, reference is made to FIG. 2. FIG. 2 is a schematic diagram of an electricity consumption predicting system 200 applied for a processing machine according to an embodiment of the present disclosure. The electricity consumption predicting system 200 has substantially the same configuration as the electricity consumption predicting system 100 except for a data extracting module 250 and a model generating module 260. The data extracting module 250 is electrically coupled to a electricity meter 270 and a controller 280. The controller 280 is configured to control the processing machine to execute processing actions according to the processing program. The electricity meter 270 is configured to measure an electricity consumption value of the processing machine. When the model information is generated initially, the processing machine may execute the test processing program first and test electricity consumption information is measured when the processing machine executes the test processing program. For example, the data extracting module 250 extracts the test processing program from a controller 280 signal and extracts the test electricity consumption information from an electricity meter 270 signal so that the test processing program and the test electricity consumption information are taken as a data source for generating the model information. For example, the test processing program of the controller 280 may be designed to include processing parameters of different rotational speeds, and the electricity meter 270 may measure electricity consumption values of the processing machine with different rotational speeds in real time. The data extracting module 250 then sends the test processing program and the test electricity consumption information to the model generating module 260 in order to generate the model information.

The model generating module 260 generates a plurality of functional information according to the test processing program and the test electricity consumption information. The functional information is data of different processing parameters and corresponding electricity consumption values. For example, regarding to functional information of spindle rotational speed, in a condition of rotational speed 0-6000 revolutions per minute (RPM), an electricity consumption value is 10 KW-50 KW when the processing machine is in an idle state, and an electricity consumption value is 40 KW-120 KW when the processing machine is in an cutting state. For another example, regarding to functional information of feed rate (in x-axis, y-axis, z-aixs), an electricity consumption value is 10 KW-15 KW in a condition of fast feeding 30 m/min, and an electricity consumption value is 10 KW-60 KW in a condition of feed rate 0-6000 mm/min. The model generating module 260 writes the functional information into the knowledge database 110 for storage. The mapping module 130 maps the functional information to make the model generating module generate the model information (e.g., a fitting polynomial curve).

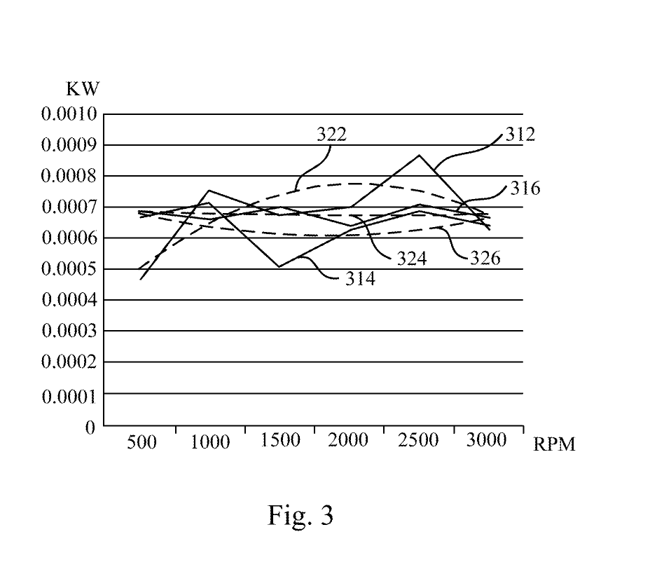

In order to give an example to describe the functional information and the polynomial curve, reference is made to FIGS. 3-6, which are schematic diagrams of model information according to the present disclosure. FIG. 3 indicates an electricity consumption value model of the spindle rotational speed, horizontal axis indicates rotational speed, unit of the horizontal axis is RPM, longitudinal axis indicates electricity consumption value, and unit of the longitudinal axis is KW. The functional information 312-316 respectively corresponds to model information 322-326, which is executed curve fitting by using quadratic polynomial. In the present embodiment, a polynomial of the model information 322 is y=−3E-06x²+2E-05x+3E-05, a polynomial of the model information 324 is y=8E-08x²−6E-07x+7E-05, and a polynomial of the model information 326 is y=1E-06x²−7E-06x+7E-05.

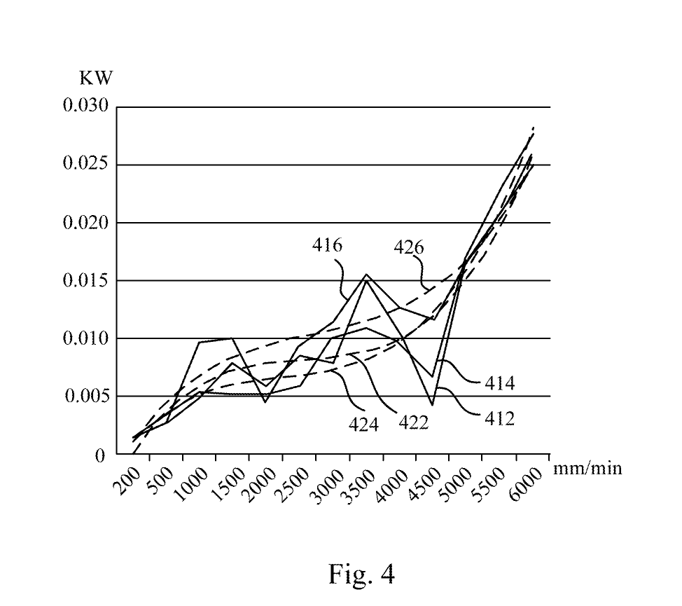

FIG. 4 indicates an electricity consumption value model of feeding in an x-axis, horizontal axis indicates feed rate, unit of the horizontal axis is mm/min, longitudinal axis indicates electricity consumption value, and unit of the longitudinal axis is KW. The functional information 412-416 respectively corresponds to model information 422-426, which is executed curve fitting by using cubic polynomials. In the present embodiment, a polynomial of the model information 422 is y=5E-05x³+0.0009x²+0.0059x−0.0049, a polynomial of the model information 424 is y=5E-05x³−0.0008x²+0.0045x−0.0029, and a polynomial of the model information 426 is y=4E-05x³−0.0007x²+0.0052x−0.0034.

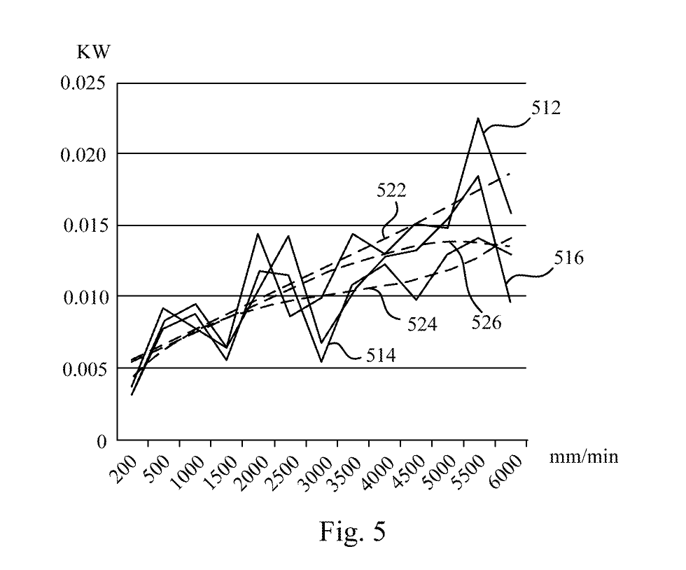

Similarly, FIG. 5 indicates an electricity consumption value model of feeding in a y-axis, horizontal axis indicates feed rate, unit of the horizontal axis is mm/min, longitudinal axis indicates electricity consumption value, and unit of the longitudinal axis is KW. The functional information 512-516 respectively corresponds to model information 522-526, which is executed curve fitting by using cubic polynomials. In the present embodiment, a polynomial of the model information 522 is y=2E-06x³−4E-05x²+0.0013x+0.0042, a polynomial of the model information 524 is y=1E-05x³−0.0003x²+0.0027x+0.0020, and a polynomial of the model information 526 is y=−6E-06x³+7E-05x²+0.0008x+0.0046.

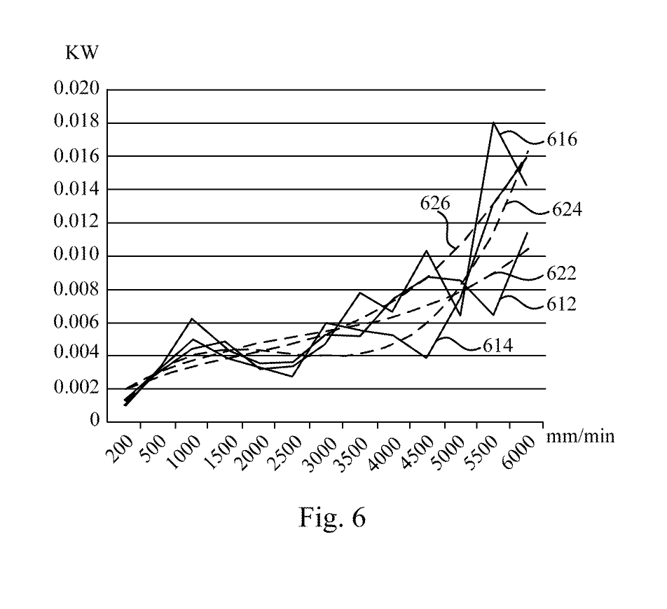

Similarly, FIG. 6 indicates an electricity consumption value model of feeding in z-axis, horizontal axis indicates feed rate, unit of the horizontal axis is mm/min, longitudinal axis indicates electricity consumption value, and unit of the longitudinal axis is KW. The functional information 612-616 respectively corresponds to model information 622-626, which is executed curve fitting by using cubic polynomials. In the present embodiment, a polynomial of the model information 622 is y=1E-05x³−0.0002x²+0.0015x+0.0006, a polynomial of the model information 624 is y=4E-05x³−0.0006x²+0.0034x−0.0015, and a polynomial of the model information 626 is y=1E-05x³−0.0002x²+0.0012x+0.0008.

After the model generating module 260 generates the model information, the model generating module 260 writes the model information into the knowledge database 110 for storage. As a result, the model information may be used to predict electricity consumption values (i.e., predictive block electricity consumption values) according to actions (e.g., moving, rotating, cutting, etc) of the processing machine defined in the NC program blocks before the processing machine produces a work piece in practice, and then to generate a predictive total electricity consumption value of the processing program (i.e., the predictive processing program total electricity consumption value).

In an embodiment, the model information in the knowledge database 110 may be updated according to processing programs of produced work pieces. The electricity meter 270 measures a practical electricity consumption value of the processing machine in real time during a work piece producing process. The data extracting module 250 extracts corresponding practical electricity consumption information form the electricity meter 270 signal according to the each of the NC program blocks, and sends the practical electricity consumption information to the decomposition module 120. The decomposition module 120 updates the model information in the knowledge database 110 according to the each of the NC program block and the corresponding practical electricity consumption information. The mapping module 130 further maps the updated functional information to update the model information.

In an embodiment, the predicting module 140 may determine whether the predictive processing program total electricity consumption value meets an electricity consumption standard. The electricity consumption standard may be decided according to actual demand by an industrial user. For example, there is an upper limit of a total electricity consumption value per month of a whole factory, and factory workers may respectively set an electricity consumption standard for every processing machine. Alternatively, the factory workers may predict a total electricity consumption value of all processing machines every month, and determine whether a sum is lower than the upper limit of total electricity consumption value per month of the factory after summing up. When the predicting module 140 determines that the predictive processing program total electricity consumption value meets the electricity consumption standard, for example, the electricity consumption value of every processing machine is lower than the electricity consumption standard thereof or the summed total electricity consumption value of all processing machines is lower than the upper limit of the total electricity consumption value of the factory, which indicates that the processing program meets the electricity consumption value required by the factory workers, and therefore the factory workers can use the processing program for production.

In contrast, when the predicting module 140 determines that the predictive processing program total electricity consumption value doesn't meet the electricity consumption standard (e.g., the predictive processing program total electricity consumption value exceeds the electricity consumption standard), the predicting module 140 may suggest an adjusted processing information. Specifically, the predicting module 140 adjusts a corresponding processing information corresponding to a NC program block of the NC program blocks to generate the adjusted processing information, and replaces the corresponding processing information with the adjusted processing information to update the corresponding processing information. In other words, the predicting module 140 adjusts the processing information to adjust the predictive block electricity consumption value and further adjusts the predictive processing program total electricity consumption value.

Similar to above description, the mapping module 130 generate a plurality of adjusted predictive block electricity consumption values according to the each of the NC program blocks, the corresponding processing information thereof and the model information. The predicting module 140 sums up the predictive adjusted block electricity consumption values to generate a predictive adjusted processing program total electricity consumption value. The predicting module 140 then determines whether the predictive adjusted processing program total electricity consumption value meets the electricity consumption standard. When the predicting module 140 determines that the predictive adjusted processing program total electricity consumption value meets the electricity consumption standard, it indicates that the adjusted processing program meets the electricity consumption value required by the factory workers. Therefore, the predicting module 140 sends the adjusted processing information to the controller 280 in order to adjust the processing program, and the factory workers can use the adjusted processing program for production.

In contrast, when the predicting module 140 determines that the predictive adjusted processing program total electricity consumption value doesn't meet the electricity consumption standard (e.g., the predictive adjusted processing program total electricity consumption value exceeds the electricity consumption standard), the predicting module 140 keeps suggesting another adjusted processing information until the generated predictive adjusted processing program total electricity consumption value meets the electricity consumption standard.

In another embodiment of adjusted processing information, without affecting processing accuracy, the predicting module 140 first determines a maximum feed rate of the processing machine in a condition of stable electricity consumption, which is determined from a curve diagram of electricity consumption value and rotational speed. When a slope of a curve is higher than a particular value, the predicting module 140 determines that electricity consumption of the processing machine is unstable. The particular value for slope may be set according to different processing machines. The predicting module 140 then determines a spindle rotational speed according to the feed rate and a load of a cutting tool, and generates a predictive adjusted processing program total electricity consumption value according to the model information accordingly, and determines whether the predictive adjusted processing program total electricity consumption value meets the electricity consumption standard. When the predicting module 140 determines that the predictive adjusted processing program total electricity consumption value doesn't meet the electricity consumption standard, the predicting module 140 reduces the feed rate (e.g., reduces 10%, 3%), determines a spindle rotational speed according to the reduced feed rate and the load of the cutting tool, and generates a predictive adjusted processing program total electricity consumption value according to the model information accordingly until the generated predictive adjusted processing program total electricity consumption value meets the electricity consumption standard. The predicting module 140 sends the adjusted feed rate and the spindle rotational speed to the controller 280 in order to adjust the processing program. Therefore, the processing machine can executes production according to the adjusted processing program. The adjustments of spindle rotational speed and the feed rate are merely for the purpose of exemplary description and not of limitation to the present disclosure.

As a result, when the predictive total electricity consumption value of the processing program doesn't meet the electricity consumption standard, the electricity consumption predicting system 200 of the present disclosure can suggest the adjusted processing information so that the adjusted processing program meets the electricity consumption standard without affecting processing accuracy.

In practice, the knowledge database 110 can be stored in a storage device, such as a hard disk, any non-transitory computer readable storage medium, or a database accessible from network. Those of ordinary skill in the art can think of the appropriate implementation of the knowledge database 110 without departing from the spirit and scope of the present disclosure.

The above-mentioned decomposition module 120, the mapping module 130, the predicting module 140, the data extracting module 250 and the model generating module 260 can be implemented as software, hardware and/or firmware. For example, if the execution speed and accuracy is a primary consideration, then each module and each unit can be mainly selected from hardware and/or software; if the design flexibility is a primary consideration, then each module and each unit can be mainly selected from software; and alternatively, each module and each unit can make use of software, hardware and firmware cooperatively. It should be known that, the above-mentioned examples are not classified as better or worse and they are not used to limit the invention. Those of skills in the art can flexibly select the specific implementation for each module and each unit, depending on the current demand. In an embodiment, the decomposition module 120, the mapping module 130, the predicting module 140, the data extracting module 250 and the model generating module 260 can be integrated into a central processing unit (CPU). Alternatively, in another embodiment, the decomposition module 120, the mapping module 130, the predicting module 140, the data extracting module 250 and the model generating module 260 may be computer programs that are stored in a storage device, and the computer programs includes a plurality of program instructions. The program instructions can be executed by the CPU so that the electricity consumption predicting system performs functions of the above modules.

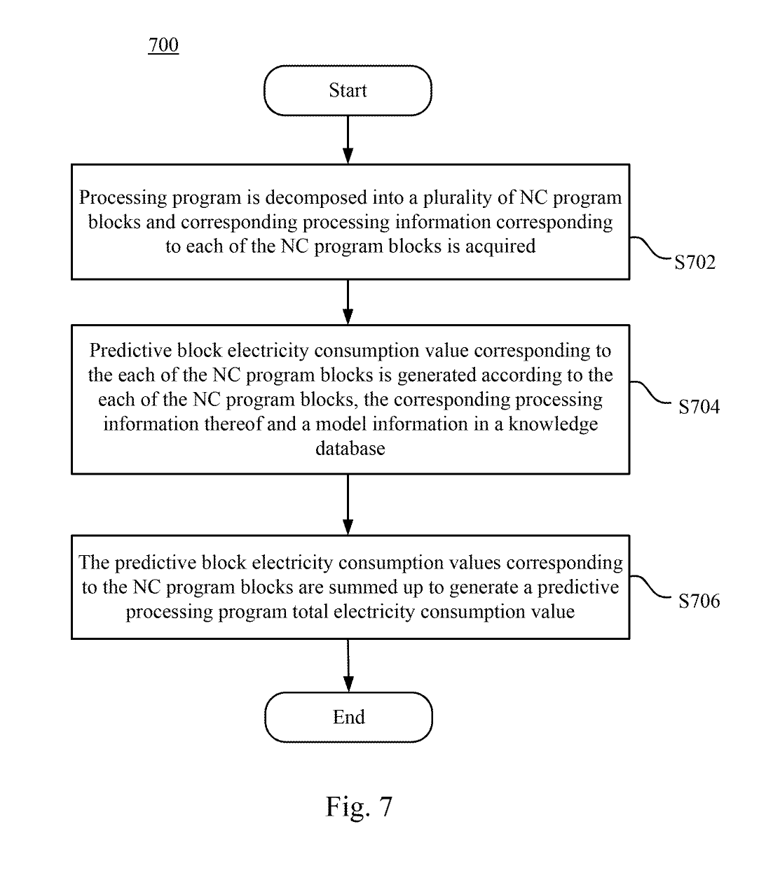

FIGS. 7-11 are flow charts of electricity consumption predicting methods 700-1100 applied for a processing machine according to some embodiments of the present disclosure. The electricity consumption predicting method 700 includes steps S702-S706, the electricity consumption predicting method 800 includes steps S802-S806, the electricity consumption predicting method 900 includes steps S902-S904, the electricity consumption predicting method 1000 includes steps S1002-S1008, the electricity consumption predicting method 1100 includes steps S1102-S1106, and the electricity consumption predicting methods 700-1100 can be applied to electricity consumption predicting systems 100 and 200 as shown in FIGS. 1 and 2. However, those skilled in the art should understand that the mentioned steps in the present embodiment are in an adjustable execution sequence according to the actual demands except for the steps in a specially described sequence, and even the steps or parts of the steps can be executed simultaneously.

In step S702, a processing program is decomposed into a plurality of NC program blocks and corresponding processing information corresponding to each of the NC program blocks is acquired.

In step S704, a predictive block electricity consumption value corresponding to the each of the NC program blocks is generated according to each of the NC program blocks, the corresponding processing information thereof and model information in a knowledge database. The model information is used for recording a corresponding relation between the each of the NC program blocks and an electricity consumption value thereof.

In step S706, the predictive block electricity consumption values corresponding to the NC program blocks are summed up to generate a predictive processing program total electricity consumption value.

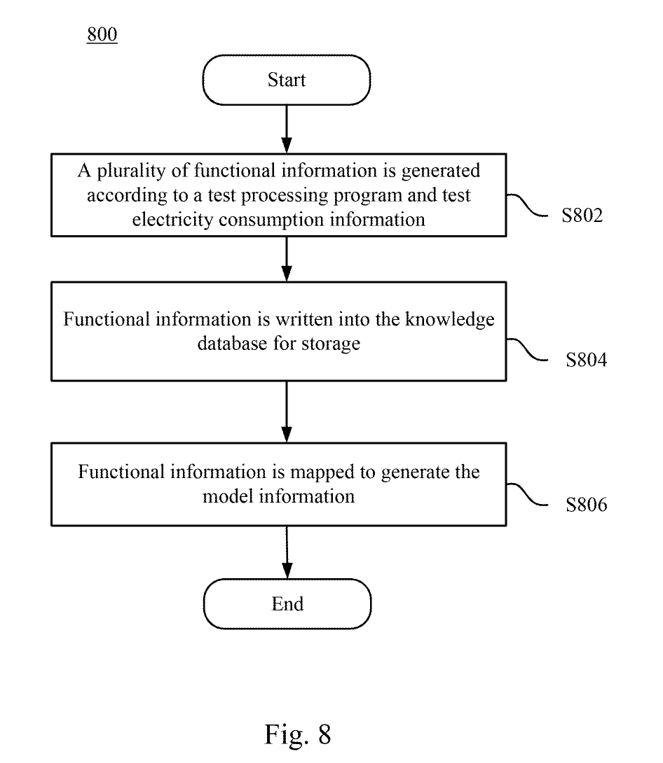

In order to generate the model information, reference is made to FIG. 8.

In step S802, a plurality of functional information (including rotational speed, feeding, and other statuses of the processing machine) is generated according to a test processing program and test electricity consumption information.

In step S804, the plurality of functional information is written into the knowledge database for storage.

In step S806, the plurality of functional information is mapped to generate the model information.

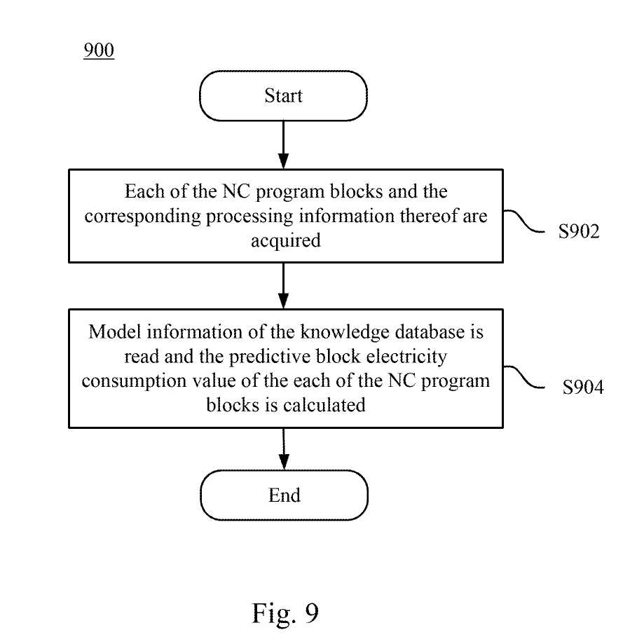

In order to specifically describe the step of generating the predictive block electricity consumption value, reference is made to FIG. 9.

In step S902, the each of the NC program blocks and the corresponding processing information thereof (including rotational speed, feeding, processing time, moving distance, etc) are acquired.

In step S904, the model information of the knowledge database is read and the predictive block electricity consumption value of the each of the NC program blocks is calculated.

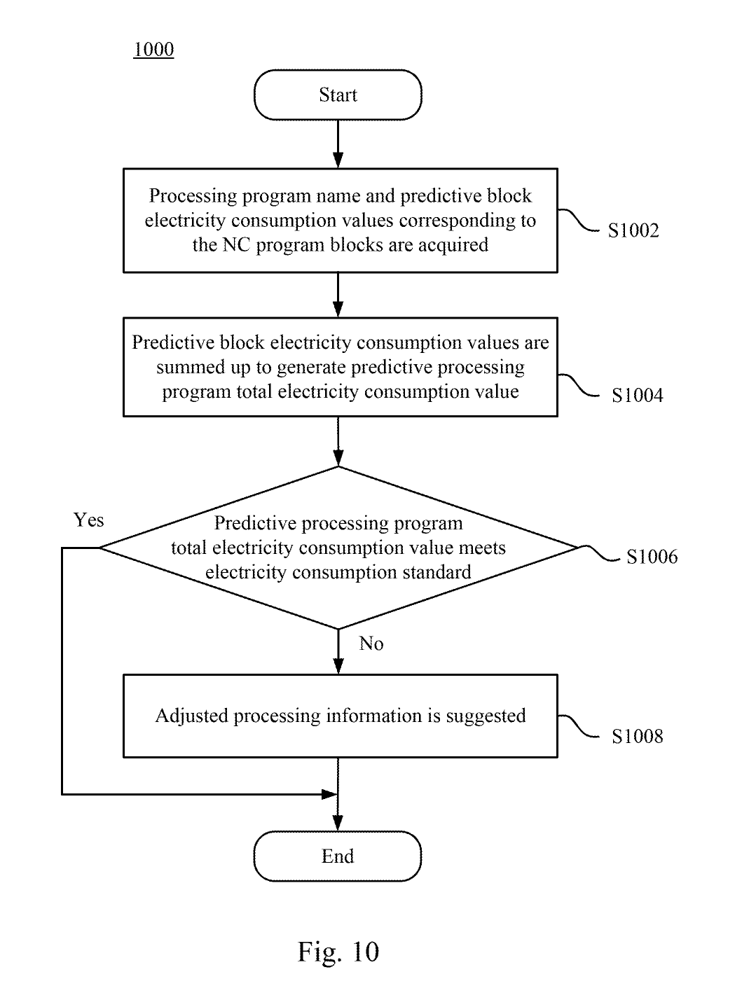

In order to specifically describe the step of generating the processing program total electricity consumption value and determining whether the processing program total electricity consumption value meets the electricity consumption standard, reference is made to FIG. 10.

In step S1002, a processing program name and the predictive block electricity consumption values corresponding to the NC program blocks are acquired.

In step S1004, the predictive block electricity consumption values are summed up to generate the predictive processing program total electricity consumption value.

In step S1006, a determination is made regarding whether the predictive processing program total electricity consumption value meets the electricity consumption standard.

If the determination is made in which the predictive processing program total electricity consumption value doesn't meet the electricity consumption standard in step S1006, adjusted processing information is then suggested in step S1008.

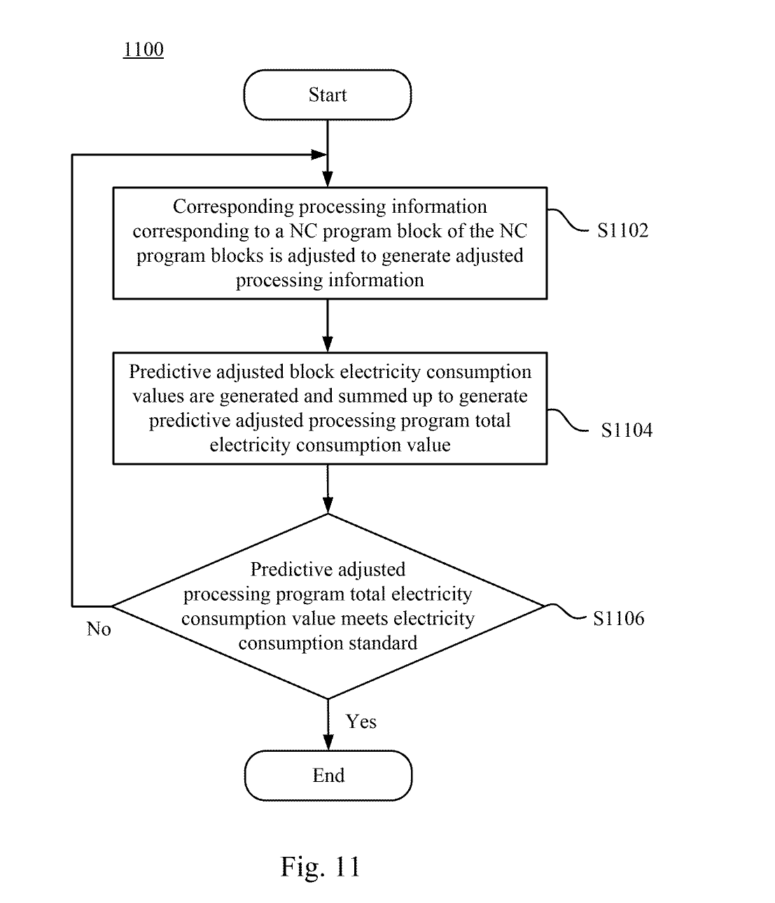

In order to specifically describe the step of suggesting the adjusted processing information, reference is made to FIG. 11. In step S1102, corresponding processing information corresponding to a NC program block of the NC program blocks is adjusted to generate adjusted processing information.

In step S1104, a plurality of predictive adjusted block electricity consumption values are generated and summed up to generate a predictive adjusted processing program total electricity consumption value

In step 1106, a determination is made regarding whether the predictive adjusted processing program total electricity consumption value meets the electricity consumption standard.

If the determination is made in which the predictive processing program total electricity consumption value doesn't meet the electricity consumption standard in step S1106, then the steps S1102-S1104 are executed repeatedly until the determination is made in which the predictive processing program total electricity consumption value meets the electricity consumption standard in step S1106.

After the predictive block electricity consumption values and the predictive processing program total electricity consumption value are calculated, the present disclosure may provide diagram presentation to the factory workers for reference or appropriate adjustment.

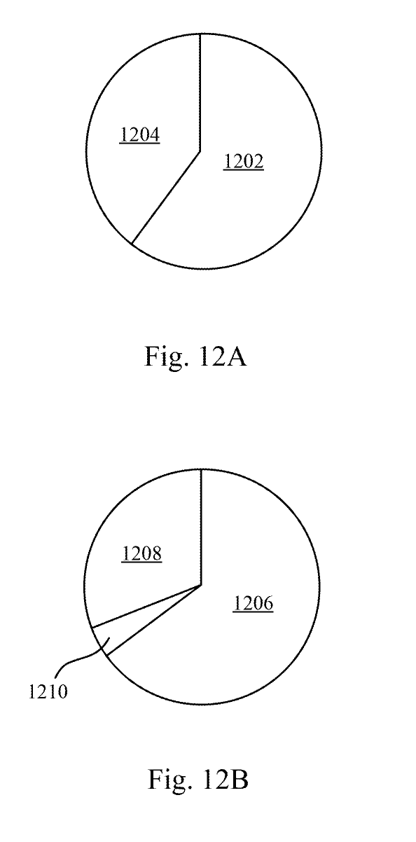

For example, the present disclosure can display proportional distribution of predictive processing program total electricity consumption value. As shown in FIG. 12A, an area 1202 indicates motor electricity consumption, and an area 1204 indicates non-motor electricity consumption. Moreover, the present disclosure can also display proportional distribution of motor electricity consumption. As shown in FIG. 12B, an area 1206 indicates cutting electricity consumption, an area 1208 indicates idle electricity consumption, and an area 1210 indicates feeding electricity consumption.

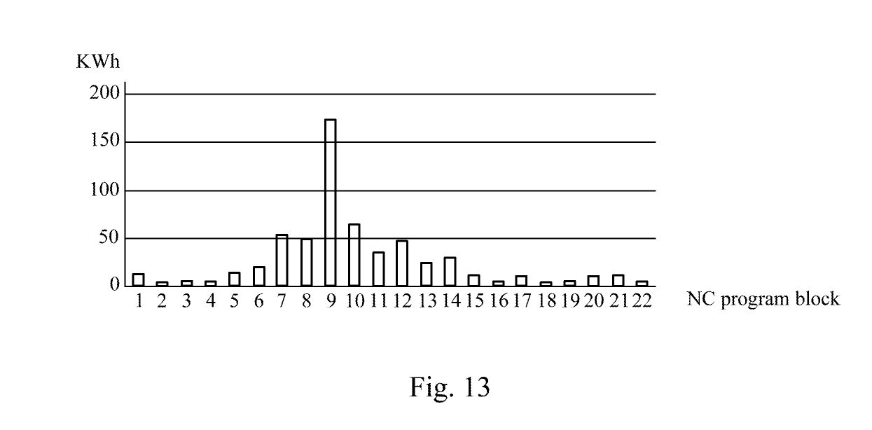

For another example, the present disclosure can display an electricity consumption value of the each of the predictive blocks in the processing program. As shown in FIG. 13, horizontal axis indicates numbers of the NC program blocks, longitudinal axis indicates electricity consumption value, and unit of the longitudinal axis is kilowatt hour (KWh). Therefore, the factory workers can know content of a NC program block with a maximum predictive electricity consumption value in the processing program and the electricity consumption value thereof so as to make appropriate adjustment.

In conclusion, through the embodiments, the present disclosure can only require the processing program that the processing machine performs on a work piece to generate the predictive processing program total electricity consumption value as a basis for estimating cost of the work piece electricity consumption value according to the model information in the knowledge database. Moreover, the present disclosure also can estimate the total electricity consumption value of the work piece produced by the processing machine according to an order quantity of the work piece, processing schedule and so on. Compared to prior art that use a smart electricity meter, the present disclosure can predicts the total electricity consumption value of work piece process before production, and the predicted total electricity consumption value is closer to electricity consumption value of the processing machine during an actual process so that the present disclosure significantly improves accuracy of predicting electricity consumption value. Therefore, the factory workers can estimate cost before the work piece production according to the predictive total electricity consumption value of the work piece. The predictive total electricity consumption value of the work piece can even used for managing processing schedule of the processing machine, or adjusting processing parameters of the processing machine appropriately.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electricity consumption predicting system applied for a processing machine, comprising:
a knowledge database, configured to store a model information, wherein the model information is used for recording a corresponding relation between each of a plurality of NC program blocks and an electricity consumption value thereof;
a decomposition module, configured to decompose a processing program into the NC program blocks and to acquire a corresponding processing information corresponding to the each of the NC program blocks;
a mapping module, configured to generate a predictive block electricity consumption value corresponding to the each of the NC program blocks according to the each of the NC program blocks, the corresponding processing information thereof and the model information; and
a predicting module, configured to sum up the predictive block electricity consumption values corresponding to the NC program blocks to generate a predictive processing program total electricity consumption value.

2. The electricity consumption predicting system of claim 1, further comprising:
a model generating module, configured to generate a plurality of functional information according to a test processing program and a test electricity consumption information, and to write the functional information into the knowledge database for storage, wherein the mapping module maps the functional information to make the model generating module generate the model information.

3. The electricity consumption predicting system of claim 2, further comprising:
a data extracting module, configured to extract the test processing program and the test electricity consumption information from a controller signal and an electricity meter signal respectively, and to send the test processing program and the test electricity consumption information to the model generating module.

4. The electricity consumption predicting system of claim 3, wherein the data extracting module extracts a corresponding practical electricity consumption information from the electricity meter signal according to the each of the NC program blocks, and sends the corresponding practical electricity consumption information to the decomposition module; the decomposition module updates the functional information in the knowledge database according to the each of the NC program blocks and the corresponding practical electricity consumption information; and the mapping module further maps the updated functional information to update the model information.

5. The electricity consumption predicting system of claim 1, wherein when the predicting module determines that the predictive processing program total electricity consumption value doesn't meet an electricity consumption standard, the predicting module adjusts a corresponding processing information corresponding to a NC program block of the NC program blocks to generate an adjusted processing information and replaces the corresponding processing information with the adjusted processing information to update the corresponding processing information, the mapping module generates a plurality of predictive adjusted block electricity consumption values according to each of the NC program blocks, the corresponding processing information thereof and the model information, the predicting module sums up the predictive adjusted block electricity consumption values to generate a predictive adjusted processing program total electricity consumption value; and
when the predicting module determines that the predictive adjusted processing program total electricity consumption value meets the electricity consumption standard, the predicting module sends the adjusted processing information to a controller to adjust the processing program.

6. The electricity consumption predicting system of claim 2, wherein the model generating module writes the model information into the knowledge database.

7. The electricity consumption predicting system of claim 1, wherein the processing information comprises a moving distance information and a processing time information of a spindle of the processing machine calculated by the decomposition module according to the NC program blocks.

8. An electricity consumption predicting method applied for a processing machine, wherein the electricity consumption predicting method comprises:
decomposing a processing program into a plurality of NC program blocks and acquiring a corresponding processing information corresponding to each of the NC program blocks;
generating a predictive block electricity consumption value corresponding to the each of the NC program blocks according to the each of the NC program blocks, the corresponding processing information thereof and a model information in a knowledge database, wherein the model information is used for recording a corresponding relation between the each of the NC program blocks and an electricity consumption value thereof; and
summing up the predictive block electricity consumption values corresponding to the NC program blocks to generate a predictive processing program total electricity consumption value.

9. The electricity consumption predicting method of claim 8, further comprising:
generating a plurality of functional information according to a test processing program and a test electricity consumption information, and writing the functional information into the knowledge database for storage; and
mapping the functional information to generate the model information.

10. The electricity consumption predicting method of claim 9, further comprising:
extracting the test processing program and the test electricity consumption information from a controller signal and an electricity meter signal respectively.

11. The electricity consumption predicting method of claim 10, further comprising:
extracting a corresponding practical electricity consumption information from the electricity meter signal according to the each of the NC program blocks;
updating the functional information in the knowledge database according to the each of the NC program blocks and the corresponding practical electricity consumption information; and
mapping the updated functional information to update the model information.

12. The electricity consumption predicting method of claim 8, further comprising:
adjusting a corresponding processing information corresponding to a NC program block of the NC program blocks to generate an adjusted processing information when a determination is made in which the predictive processing program total electricity consumption value doesn't meet an electricity consumption standard;
replacing the corresponding processing information with the adjusted processing information to update the corresponding processing information; and
generating a plurality of predictive adjusted block electricity consumption values according to the each of the NC program blocks, the corresponding processing information thereof and the model information;
summing up the predictive adjusted block electricity consumption values to generate a predictive adjusted processing program total electricity consumption value; and
sending the adjusted processing information to a controller to adjust the processing program when a determination is made in which the predictive adjusted processing program total electricity consumption value meets the electricity consumption standard.

13. The electricity consumption predicting method of claim 9, further comprising:
writing the model information into the knowledge database.

14. The electricity consumption predicting method of claim 8, wherein the processing information comprises a moving distance information and a processing time information of a spindle of the processing machine that are calculated according to the NC program blocks.
